(19) United States
(12) Patent Application Publication
(10) Pub. No.: US 2024/0106115 A1
(43) Pub. Date: Mar. 28, 2024

(54) LOW-LOSS SMALL FORM-FACTOR BUTLER MATRIX

(71) Applicant: QUALCOMM Incorporated, San Diego, CA (US)

(72) Inventors: Haim WEISSMAN, Haifa (IL); Idan Michael HORN, Hod Hasharon (IL); Elimelech GANCHROW, Zichron Yaakov (IL)

(21) Appl. No.: 17/950,367

(22) Filed: Sep. 22, 2022

(51) Int. Cl. H01Q 3/36; H01Q 9/04; H05K 1/02; H05K 1/11

(52) U.S. Cl. CPC H01Q 3/36; H01Q 9/0407; H05K 1/0243; H05K 1/115; H05K 2201/10098

(57) ABSTRACT

Techniques are provided for reducing the form factor and insertion losses of beamforming networks. An example beamforming network configured to feed a phased array of antenna elements includes a first group of microstrip elements on a first layer of a printed circuit board, a second group of microstrip elements on a second layer of the printed circuit board, a metal layer disposed between the first layer and the second layer, and a plurality of vias configured to couple one or more elements in the first group of microstrip elements with one or more elements in the second group of microstrip elements.

### BACKGROUND

Wireless communication devices are increasingly popular and increasingly complex. For example, mobile telecommunication devices have progressed from simple phones, to smart phones with multiple communication capabilities (e.g., multiple cellular communication protocols, Wi-Fi, BLUETOOTH® and other short-range communication protocols), supercomputing processors, cameras, etc. Wireless communication devices have antennas to support communication over a range of frequencies.

Wireless communication systems are widely deployed to provide various telecommunication services such as telephony, video, data, messaging, and broadcasts. Typical wireless communication systems may employ multiple access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is 5G New Radio (NR). 5G NR is part of a continuous mobile broadband evolution promulgated by Third Generation Partnership Project (3GPP) to meet new requirements associated with latency, reliability, security, scalability (e.g., with Internet of Things (IoT)), and other requirements. 5G NR includes services associated with enhanced mobile broadband (eMBB), massive machine type communications (mMTC), and ultra-reliable low latency communications (URLLC). Some aspects of 5G NR may be based on the 4G Long Term Evolution (LTE) standard. There exists a need for further improvements in 5G NR technology. These improvements may also be applicable to other multi-access technologies and the telecommunication standards that employ these technologies.

It is often desirable to electronically steer an antenna beam for communication purposes and/or one or more other purposes. For example, a beam of a base station may be directed toward a user equipment to better receive signals from and/or transmit signals to the user equipment. Various techniques may be used to electronically steer an antenna beam, such as altering phase shifters associated with multiple antenna elements to provide a progressive phase shift across the antenna elements, e.g., along a linear array (which may be part of a two-dimensional array). As another example, referring to FIGS. 1-3, a beam steering system 100 includes a Butler matrix 110 that may be used to select one of a set of possible phase progressions for antenna elements 120. In this example, there are eight antenna elements 120 and the Butler matrix is an 8×8 Butler matrix. As better shown in FIG. 2, a Butler matrix is a combination of fixed phase shifters 210 (only one of which is labeled in FIG. 2) and quadrature hybrids 220 (only one of which is labeled in FIG. 2) arranged in a structure that produces a number of progressive phase shifts at antenna ports 230 (e.g., AP1, AP2, AP3, AP4, AP5, AP6, AP7, AP8) corresponding to different beam directions for a signal provided to or accessed at a set of beam ports 240. An N×N Butler matrix has N antenna ports and N beam ports, and provides N phase progressions corresponding to N different beams. Butler matrixes are discussed in Cetinoneri, B., Atesal, Y. A., and Rebeiz, G. M. (2011), “An 8×8 Butler Matrix in 0.13 μm CMOS for 5-6 GHz Multibeam Applications,” IEEE Transaction son microwave theory and techniques, 59(2), 295-301 (URL: https://ieeexplore.ieee.org/abstract/document/5678820). A set of electrical lengths between a beam port and the antenna ports is different for each beam port such that the phase progression at the antenna ports is different for each beam port. While an electrical length between one beam port and one antenna port may be the same as the electrical length between another beam port and another antenna port, the set of electrical lengths (as a combination of magnitude and order of antenna port) is unique for each of the beam ports. Respective portions of a signal provided at any one of the beam ports 240 will reach each of the antenna ports 230 with a different phase and respective portions of a signal received by any one of the antenna ports 230 will reach each of the beam ports 240. Different phase portions of the received signal will be combined and received by each of the beam ports such that the signal at each beam corresponds to a different beam direction. The beam ports 240 labeled 1L, 2L, 3L, 4L correspond to first, second, third, and fourth beams to the left of boresight (of the array of the antenna elements 120) providable by the Butler matrix 110 and the beam ports 240 labeled 1R, 2R, 3R, 4R correspond to first, second, third, and fourth beams to the left of boresight providable by the Butler matrix 110. The system 100 further includes a transmit/receive selector 130 for each of the antenna elements 120 (corresponding to each of the antenna ports 230). As shown in FIG. 3, a transmit/receive selector 300, which is an example of the transmit/receive selectors 130, includes a power amplifier 310, a low noise amplifier 320, and switches 330, 340. The switches 330, 340 connect the Butler matrix 110 to the respective antenna element 120 via the power amplifier 310 for a transmit mode and connect the Butler matrix 110 to the respective antenna element 120 via the low noise amplifier 320 for a receive mode. The system 100 further includes a beam direction switch 140 (BDS) that is controlled to select a desired one of the beam ports corresponding to a desired beam. The BDS 140 is connected to a transmit/receive signaling device 150, a receive portion of which is shown in FIG. 1, including a variable gain amplifier (VGA), a mixer, a local oscillator (LO), and a local oscillator phase shifter (PS). The beam steering system 100 is an example use case for a Butler matrix, and not a limitation. Other systems and use cases may use different Butler matrix configurations.

The Butler matrix 110 includes a crossover section 250 of transmission lines connecting quadrature hybrids 260 of the Butler matrix 110 to the antenna ports 230, and thus connecting the antenna elements 120 to the quadrature hybrids 260 nearest the antenna elements 120. Connecting an N×N Butler matrix to the antenna ports (for connection to the transmit/receive selectors 130, which may be called front ends), may result in long routings and crossovers that use a large area and result in high signal attenuation, especially at millimeter-wave frequencies and sub-millimeter-wave frequencies. The crossover section 250 may consume as much as one-fourth of the area of a chip containing the matrix 110.

### SUMMARY

An example beamforming network configured to feed a phased array of antenna elements according to the disclosure includes a first group of microstrip elements on a first layer of a printed circuit board, a second group of microstrip elements on a second layer of the printed circuit board, a metal layer disposed between the first layer and the second layer, and a plurality of vias configured to couple one or more elements in the first group of microstrip elements with one or more elements in the second group of microstrip elements.

An example antenna beamforming system according to the disclosure includes a first printed circuit board layer comprising a first group of microstrip elements including quadrature hybrid elements and phase shifter elements, a second printed circuit board layer comprising a second group of microstrip elements including quadrature hybrid elements and phase shifter elements, a metal ground layer disposed between the first printed circuit board layer and the second printed circuit board layer, and a plurality of vias configured to couple one or more of the first group of microstrip elements with one or more of the second group of microstrip elements.

An example antenna beamforming system according to the disclosure includes a first section comprising a first printed circuit board layer comprising a first group of microstrip elements including quadrature hybrid elements and phase shifter elements, a second printed circuit board layer comprising a second group of microstrip elements including quadrature hybrid elements and phase shifter elements, a first metal ground layer disposed between the first printed circuit board layer and the second printed circuit board layer, a first plurality of vias configured to couple one or more of the first group of microstrip elements with one or more of the second group of microstrip elements, a plurality of input ports configured to receive a radio frequency input, a second section comprising a third printed circuit board layer comprising a third group of microstrip elements including quadrature hybrid elements and phase shifter elements, a fourth printed circuit board layer comprising a fourth group of microstrip elements including quadrature hybrid elements and phase shifter elements, a second metal ground layer disposed between the third printed circuit board layer and the fourth printed circuit board layer, a second plurality of vias configured to couple one or more of the third group of microstrip elements with one or more of the fourth group of microstrip elements, a plurality of output ports configured to output a radio frequency output to an antenna array, and a cable section configured to operably couple the first section and the second section.

An example method of fabricating a low-loss small form-factor beamforming network according to the disclosure includes disposing a first group of microstrip elements including quadrature hybrid elements and phase shifter elements on a first printed circuit board layer, disposing a second group of microstrip elements including quadrature hybrid elements and phase shifter elements on a second printed circuit board layer, disposing a metal layer between the first printed circuit board layer and the second printed circuit board layer, and coupling one or more of the first group of microstrip elements with one or more of the second group of microstrip elements with one or more vias.

Items and/or techniques described herein may provide one or more of the following capabilities, as well as other capabilities not mentioned. A beamforming network, such as a Butler matrix, may include a plurality of quadrature hybrid elements, phase shifting elements, and cross-over elements. The cross-over elements may increase the form factor of a beamforming network, and increase the insertion loss. The proposed beamforming networks may reduce the number of cross-over elements by bifurcating the network into at least two different layers. For example, half of the quadrature hybrid and phase shifter elements may be located on a first layer of a printed circuit board (PCB) and the other half of the quadrature hybrid and phase shifter elements may be located on another layer of the PCB to reduce the number of cross-over elements. A ground layer may be disposed between the two layers, and vias may be used to connect elements on the different layers. The multiple layers in the beamforming network may reduce the form-factor and insertion loss. Transmit power may be reduced and battery power may be conserved. Other capabilities may be provided and not every implementation according to the disclosure must provide any, let alone all, of the capabilities discussed. Further, it may be possible for an effect noted above to be achieved by means other than that noted, and a noted item/technique may not necessarily yield the noted effect.

### BRIEF DESCRIPTION OF THE DRAWINGS

FIG. 1 is a schematic diagram of a beam steering system.

FIG. 2 is a circuit diagram of a Butler matrix shown in FIG. 1.

FIG. 3 is a circuit diagram of a transmit/receive selector shown in FIG. 1.

FIG. 4 is a schematic diagram of a communications system.

FIG. 5 is a block diagram of a wireless communication device, examples of which are shown in FIG. 4.

FIG. 6 is the circuit diagram of the Butler matrix shown in FIG. 2 with the cross-over elements highlighted.

FIG. 7 is an example microstrip design of a 8×8 Butler matrix with the cross-over elements highlighted.

FIG. 8 is a schematic diagram of an example small form factor and low loss Butler matrix.

FIG. 9 is a perspective diagram of an example small form factor and low loss Butler matrix on a printed circuit board.

FIG. 10 includes schematic diagrams of the printed circuit board layers of the Butler matrix in FIG. 9.

FIG. 11 includes example layers of an 8×8 Butler matrix with two cross-overs and ten vias.

FIG. 12 includes example layers of an 8×8 Butler matrix with zero cross-overs and twelve vias.

FIGS. 13A and 13B include example 8×8 Butler matrices in standard and reduced form factor configurations.

FIG. 14 is a schematic diagram of an example 16×16 split Butler matrix without cross-over elements.

FIG. 15 is a schematic diagram of a 16×16 split Butler matrix with an optional amplifier.

FIG. 16 is a schematic diagram of an example 16×16 split IF-RF Butler matrix without cross-over elements.

FIG. 17 is a process flow diagram of an example method for fabricating a low-loss small form-factor beamforming network.

### DETAILED DESCRIPTION

Techniques are discussed herein for reducing the form factor and insertion losses of beamforming networks. In general, beamforming networks, such as a Butler matrix, are configured to feed a phased array of antenna elements. For example, a Butler matrix is an example of a beamforming network which may include interconnected fixed phase shifters and 3 db Hybrid couplers, and is an efficient method of feeding an array antenna with a constant phase difference between elements. The matrix may be configured to produce N orthogonally spaced beams and is typically utilized for multiple stream low power solutions. For example, Butler matrix arrays are used in 5G and mm-waves radar systems and are expected to be used in future radio access technologies (e.g., 6G systems). Prior Butler matrix designs required relatively large form factors and suffer from relatively larger insertion losses due to the multiple cross-over elements in the circuit. The insertion loss may be a significant issue, especially for a high order butler matrix such as 16×16 and when operating at high mm-waves frequencies such as in the E-Band, D-Band, etc., where additional Low Noise Amplifiers (LNAs) and Power Amplifiers (PAs) have a substantial impact on the power consumption of a system. The proposed Butler matrix designs provided herein reduce the form factor and insertion losses as compared to the prior designs. In an example, half of the hybrid couplers in a matrix are located on a first layer of a printed circuit board (PCB) and the other half of the hybrid couplers are located on another layer of the PCB to reduce the number of cross-over elements. A ground layer may be disposed between the two layers, and vias may be used to connect elements on the different layers. In an example, the number of cross-over elements in an 8×8 Butler matrix may be reduced from 16 to 4, with a form factor that is approximately 30% of prior designs. The insertion losses may also be reduced by approximately 4-5 dB. Other beamforming network configurations, however, may be used and other form factor and injection loss reductions may be realized. Further, it may be possible for an effect noted above to be achieved by means other than that noted, and a noted item/technique may not necessarily yield the noted effect.

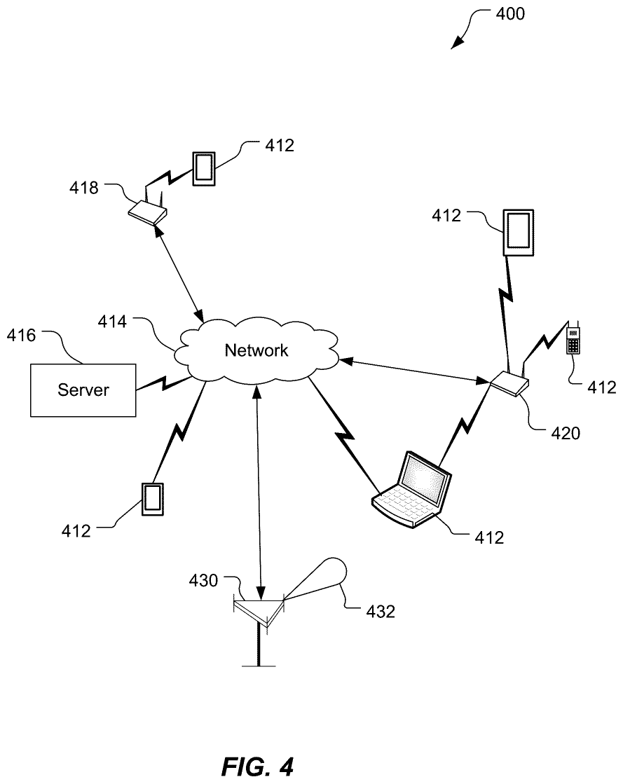

Referring to FIG. 4, a communication system 400 includes mobile devices 412, a network 414, a server 416, access points (APs) 418, 420, and a base station 430. The communication system 400 is a wireless communication system in that components of the communication system 400 can communicate with one another (at least some times) using wireless connections directly or indirectly, e.g., via the network 414, one or more of the access points 418, 420, and/or the base station 430 (and/or one or more other devices not shown, such as one or more other base stations). For indirect communications, the communications may be altered during transmission from one entity to another, e.g., to alter header information of data packets, to change format, etc. The mobile devices 412 shown are mobile wireless communication devices (although they may communicate wirelessly and via wired connections) including mobile phones (including smartphones), a laptop computer, and a tablet computer. Still other mobile devices may be used, whether currently existing or developed in the future. Further, other wireless devices (whether mobile or not) may be implemented within the communication system 400 and may communicate with each other and/or with the mobile devices 412, the network 414, the server 416, the APs 418, 420, and/or the base station 430. For example, such other devices may include internet of thing (IoT) devices, medical devices, home entertainment and/or automation devices, automotive devices, etc. The mobile devices 412 or other devices may be configured to communicate in different networks and/or for different purposes (e.g., 5G, Wi-Fi communication, multiple frequencies of Wi-Fi communication, satellite communication and/or positioning, one or more types of cellular communications (e.g., GSM (Global System for Mobiles), CDMA (Code Division Multiple Access), LTE (Long-Term Evolution), etc.), Bluetooth® communication, etc.). The base station 430 is shown separated from the network 414 but may be part of the network 414. As shown, the base station 430 is configured to select antenna beams such as a beam 432 for communication, e.g., with the beam 432 directed toward a laptop computer in this example. The base station 430 may be configured to select the beam 432 using a partially-connected set of beamforming networks as discussed herein. Devices other than a base station may be equipped with beamforming networks for selecting antenna beams as discussed herein.

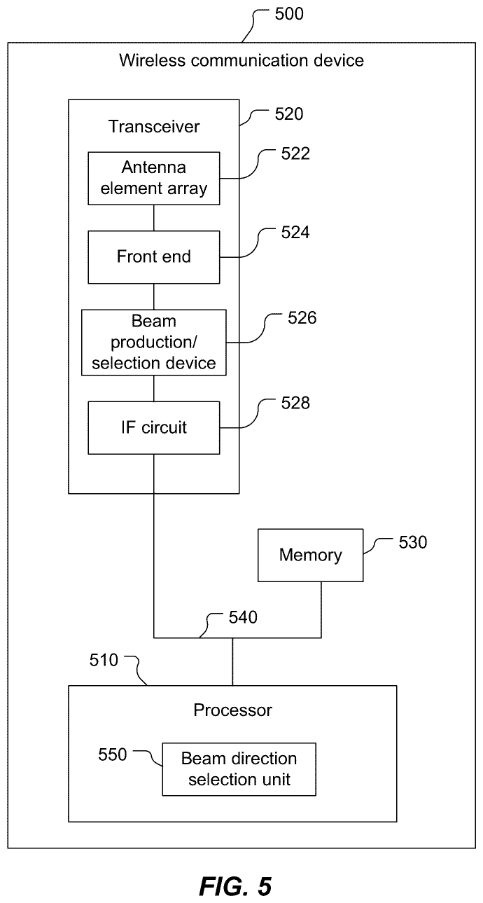

Referring also to FIG. 5, a wireless communication device 500, of which any of the mobile devices 412 and/or the base station 430 may be an example, includes a processor 510, a transceiver 520, and a memory 530 communicatively coupled to each other by a bus 540. The device 500 may include the components shown in FIG. 5. The device 500 may include one or more other components such as one or more components in addition to the components shown and/or one or more additional components included in the components shown. For example, the transceiver 520 may include a wireless transmitter, a wireless receiver, multiple antennas, etc. The memory 530 may be a non-transitory, processor-readable storage medium that includes software with processor-readable instructions that are configured to cause the processor 510 to perform functions, e.g., as discussed herein.

The transceiver 520 includes an antenna element array 522, a front end 524, a beam production/selection device 526, and an IF circuit 528 (Intermediate Frequency circuit). The antenna element array 522 includes an array of antenna elements, e.g., a one-dimensional array or a two-dimensional array (e.g., of rows and columns of antenna elements). The front end 524 is communicatively coupled to the antenna element array 522 and the beam production/selection device 526 and configured to direct outbound (transmit) signals from the beam production/selection device 526 to the antenna element array 522 and to direct inbound (receive) signals from the antenna element array 522 to the beam production/selection device 526. The beam production/selection device 526 is configured to provide multiple different phase progressions corresponding to the antenna element array 522 and to select one of the phase progressions corresponding to a desired beam direction, e.g., under control of the processor 510 (e.g., in accordance with one or more control signals received from the processor 510). The IF circuit 528 is communicatively coupled to the beam production/selection device 526 and configured to provide signals to be radiated by the antenna element array 522 and to receive and process signals that are received by, and provided to the IF circuit 528 from, the beam production/selection device 526. The IF circuit 528 may be configured to convert received baseband digital signals from the processor 510 to IF signals, to convert the IF signals to analog RF (Radio Frequency) signals (e.g., using a mixer and a digital-to-analog converter (DAC)), and to provide the RF signals to the beam production/selection device 526 for phase adjusting for a desired beam and radiation by the antenna element array 522 in the desired beam. The IF circuit 528 is configured to convert analog RF signals received by the antenna element array 522 to IF signals (e.g., using a variable gain amplifier and a mixer), to convert the IF signals to baseband digital signals (e.g., using a mixer and an analog-to-digital converter (ADC)), and to send the baseband digital signals to the processor 510. Certain examples implementing IF are described below. In other examples, the IF circuit 528 may be omitted, for example when a direct conversion architecture is utilized.

The description herein may refer to the processor 510 performing a function, but this includes other implementations such as where the processor 510 executes software (stored in the memory 530) and/or firmware. The description herein may refer to the device 500 performing a function as shorthand for one or more appropriate components (e.g., the processor 510 and the memory 530) of the device 500 performing the function. The processor 510 (possibly in conjunction with the memory 530 and, as appropriate, the transceiver 520) may include a beam direction selection unit 550. The beam direction selection unit 550 may refer to the processor 510 generally, or the device 500 generally, as performing any of the functions of the beam direction selection unit 550, with the device 500 being configured to perform the functions of the beam direction selection unit 550.

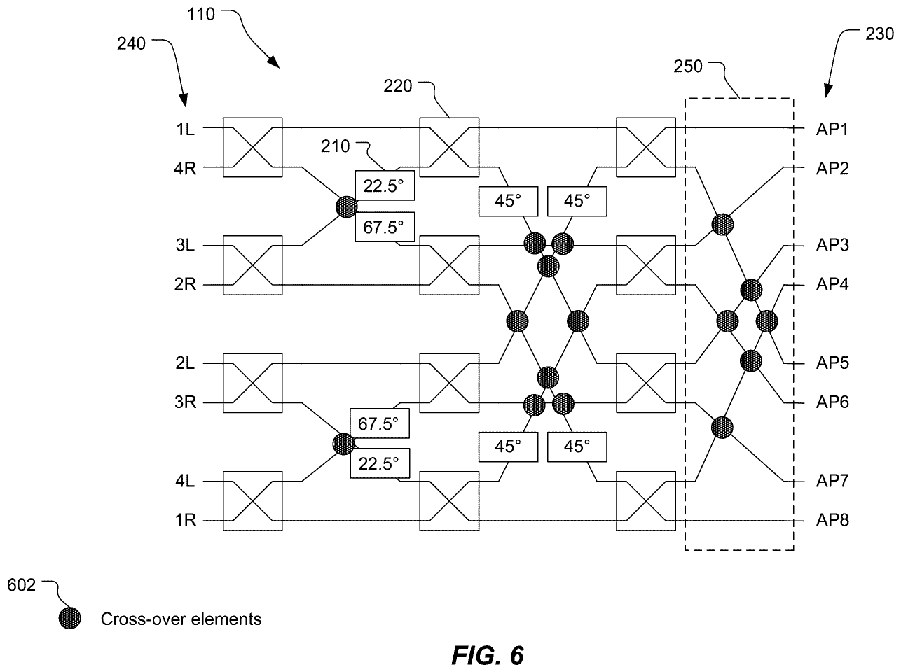

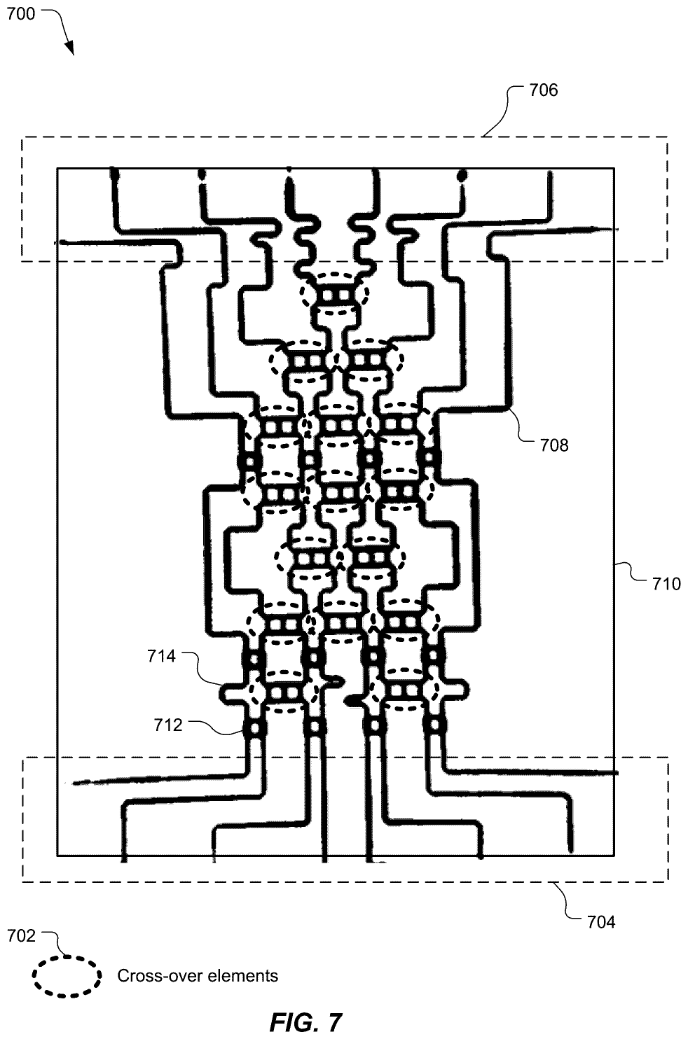

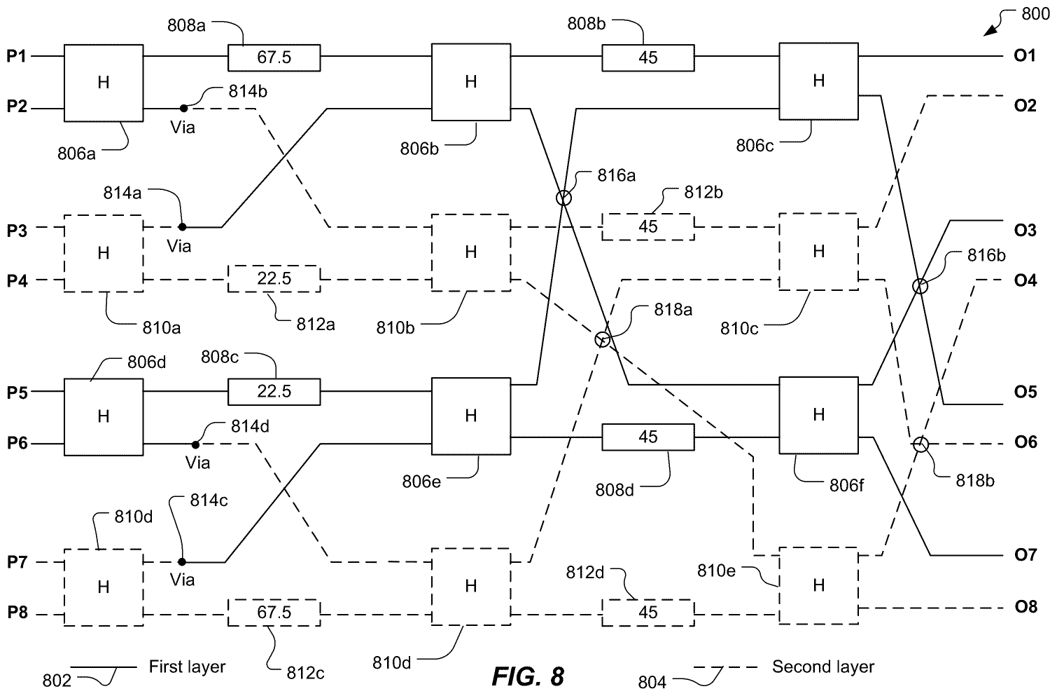

Referring to FIG. 6, the circuit diagram of the 8×8 Butler matrix of FIG. 2 is shown with cross-over elements highlighted. In general, a Butler matrix is a beamforming network used to feed a phased array of antenna elements. In an example, an 8×8 Butler matrix may include 12 quadrature hybrids 220 and 8 phase shifters 210 (i.e., 4×45°, 2×22.5°, and 2×67.5°. The circuit also includes 16 cross-over elements 602, the locations of which are highlighted with circles in FIG. 6. The cross-over elements 602 impact the overall size of the Butler matrix and the insertion loss. For example, referring to FIG. 7, an example microstrip circuit 700 including 8 inputs 704 and 8 outputs 706 (e.g., an 8×8 Butler matrix) is shown. The outputs 706 are configured to feed a phased array of antenna elements (not shown in FIG. 7). The physical cross-over elements 702 are highlighted with dashed ovals in FIG. 7. The microstrip circuit 700 includes metal microstrips 708 disposed on a single layer of a PCB substrate 710. The metal microstrips create matrix elements including the cross-over elements 702, quadrature hybrid elements 712, and the phase shifter elements 714 (only one quadrature hybrid element and one phase shifter element 714 are labeled in FIG. 7). The size of the cross-over elements 702 is based on the frequency (e.g., wavelength) of the RF signal. As a result, for a 28 GHz implementation, the overall size of the microstrip circuit 700 is approximately 11 cm×9 cm. Further, at 28 GHz, each of the cross-over elements 702 may contribute approximately 0.5 dB of insertion loss, and the measured insertion loss at each output port is approximately 18 dB.

Referring to FIG. 8, a schematic diagram of an example small form factor and low loss Butler matrix 800 is shown. The matrix 800 is an example of the 8×8 Butler matrix 110 including 8 input ports (i.e., P1-P8) and 8 outputs (i.e., O1-O8). In contrast to the microstrip circuit 700 in FIG. 7 (e.g., a single layer) the matrix 800 includes microstrip lines on a first layer 802 and microstrip lines on a second layer 804. The first layer 802 includes a first group of elements illustrated with solid lines in FIG. 8. The first group of elements on the first layer 802 includes six quadrature hybrids 806a-806f, four phase shifters 808a-808d, and two cross-overs 816a-816b. The second group of elements on the second layer 804 also includes six quadrature hybrids 810a-810f, four phase shifters 812a-812d, and two cross-overs 818a-818b. The number and configurations of the elements in the layers 802, 804 are examples, and not limitations, as other combinations and configurations of elements may be used. The first layer 802 and the second layer 804 may be disposed on separate layers of a PCB and may be separated by a metal ground layer. A plurality of via structures 814a-814d are used to couple elements on the first and second layers 802, 804. The via structures 814a-814d may be electrically isolated from the ground layer between the first and second layers 802, 804, and configured to electrically couple components on the first and second layers 802, 804. For example, a first via 814a may be configured to couple a first quadrature hybrid 810a disposed on the second layer 804 with a second quadrature hybrid 806b disposed on the first layer 802. The other via structures 814b-814d may be similarly configured to couple other components as depicted in FIG. 8. The matrix 800 reduces the number of cross-over elements from the 16 required in the microstrip circuit 700, to 4 (i.e., 816a, 816b, 818a, 818b). This reduction enables a smaller form factor and a reduction in the insertion losses by a factor of 4-5 dB.

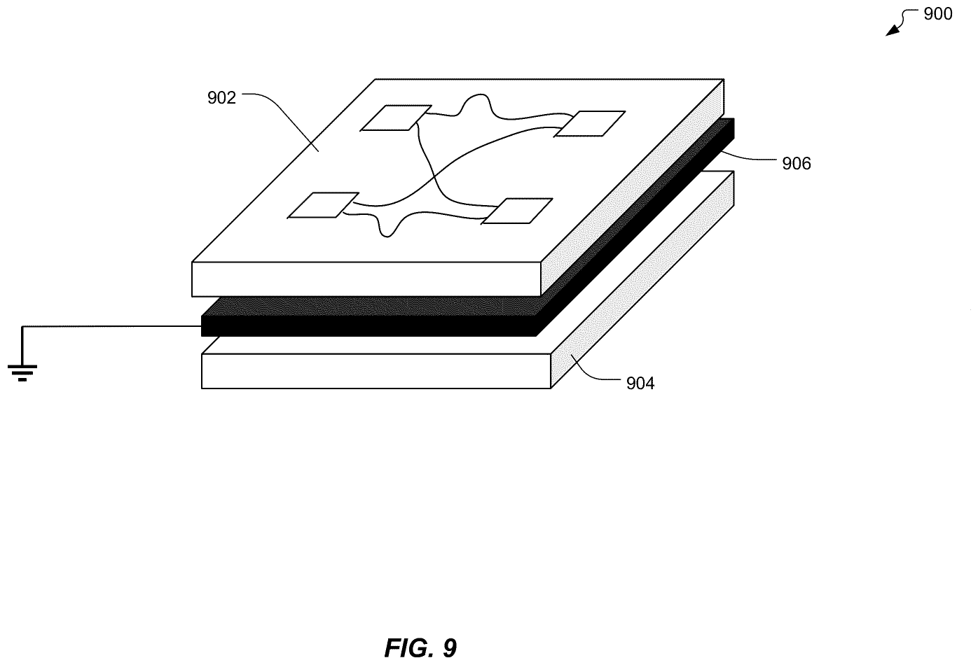

Referring to FIG. 9, with further reference to FIG. 8, a perspective diagram of an example small form-factor and low-loss Butler matrix on a PCB 900 is shown. The PCB 900 includes a first layer 902 and a second layer 904. A metal ground layer 906 is disposed between the first and second layers 902, 904. In an example, the first layer 902 may include the first group of components depicted in the first layer 802 of the matrix 800, and the second layer 904 may include the second group of components depicted in the second layer 804 of the matrix 800. Vias, such as the via structures 814a-814d, may be used to electrically couple components in the first and second layers 902, 904.

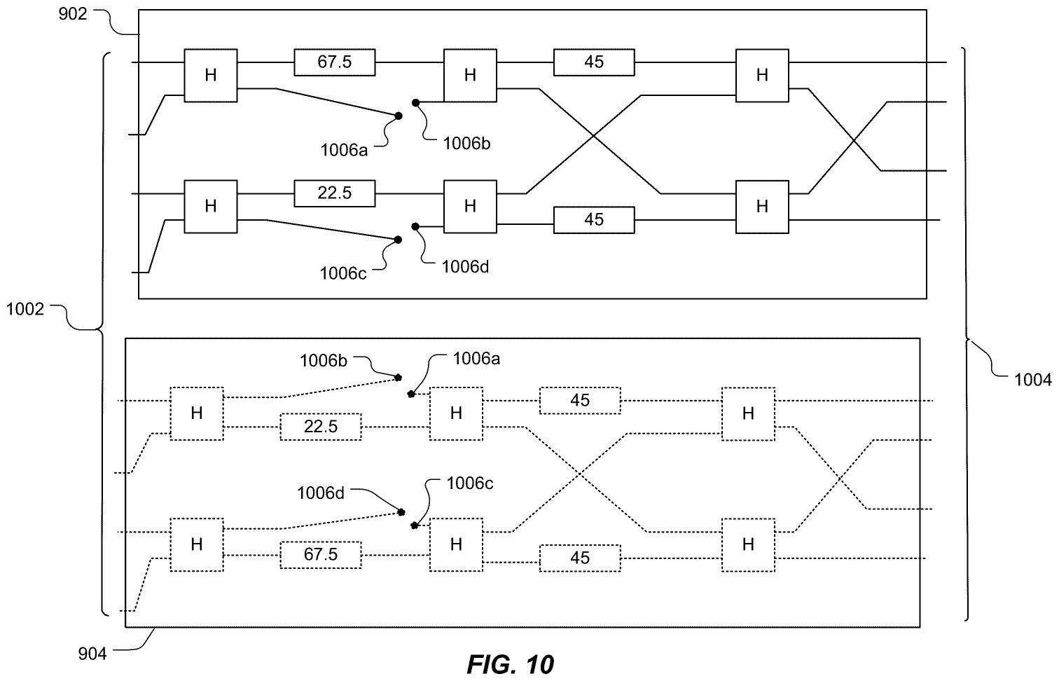

Referring to FIG. 10, schematic diagrams of the PCB layers of the Butler matrix in FIG. 9 are shown. In an example, the first layer 902 and the second layer 904 may comprise known PCB materials such as glass fiber epoxy laminates (e.g., FR4), and the components may be formed with metallic microstrip lines that are deposited on, or disposed within, the PCB material. The dimensions of the quadrature hybrids, phase shifters, and cross-over elements may be based on the frequencies of the input signals as known in the art. In an example, the metal ground layer 906 (not shown in FIG. 10) may comprise copper cladding disposed between the first and second layers 902, 904 and operably coupled to ground. Other metallization techniques may also be used to create the metal ground layer 906. The first layer 902 and the second layer 904 may be arranged such that eight input connectors 1002 are located on a first edge of the PCB 900 and eight output connectors 1004 are located on a second edge of the PCB 900. In an example, half of the input and output connectors 1002, 1004 are located on the first layer 902, and the other half of the connectors 1002, 1004 are located on the second layer 904. Four vias 1006a-1006d are configured to couple components on the first layer 902 with components on the second layer. In an example, the estimated via loss is approximately 0.2-0.3 dB. The locations of the vias 1006a-1006d are examples, and not limitations, as other locations may be used to reduce the insertion losses. For example, the number of vias may be increased to reduce the number of cross-overs.

In an example, referring to FIGS. 8-10, a low-loss small form-factor antenna beamforming system may include a first printed circuit board layer (e.g., the first layer 902) comprising a first group of microstrip elements including quadrature hybrid elements (e.g., quadrature hybrids 806a-806f) and phase shifter elements (e.g., phase shifters 808a-808d), a second printed circuit board layer (e.g., the second layer 902) comprising a second group of microstrip elements including quadrature hybrid elements (e.g., quadrature hybrids 810a-810f) and phase shifter elements (e.g., phase shifters 812a-812d), a metal ground layer 906 disposed between the first printed circuit board layer and the second printed circuit board layer, and a plurality of vias (also referred to as via elements such as the vias 1006a-1006d) configured to couple one or more of the first group of microstrip elements with one or more of the second group of microstrip elements. The first printed circuit board layer, the second printed circuit board layer, and the metal ground layer may be combined in a single printed circuit board. A plurality of input ports 1002 may be disposed on a first edge of the printed circuit board and a plurality of output ports 1004 may be disposed on a second edge of the printed circuit board. The single printed circuit board may be a rectangle shape with a length dimension of approximately 4 centimeters and a width dimension of approximately 3.5 centimeters. The first group of microstrip elements may include one or more cross-over elements (e.g., 816a-816b), and the second group of microstrip elements may include one or more cross-over elements (e.g., 818a-818b). Various configurations of microstrip elements and vias may be used. In an example, the plurality of vias may include 4 vias, the first group of microstrip elements may include two cross-over elements, and the second group of microstrip elements may include two cross-over elements. The plurality of vias may include 10 vias, the first group of microstrip elements may include one cross-over elements, and the second group of microstrip elements may include one cross-over elements. The plurality of vias may include 12 vias. The first printed circuit board layer may further comprise a first plurality of input ports and a first plurality of output ports, and the second printed circuit board layer may further comprise a second plurality of input ports and a second plurality of output ports.

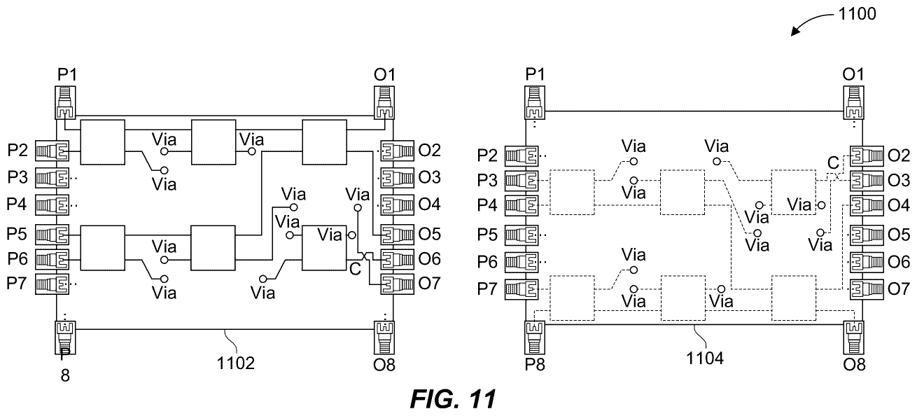

Referring to FIG. 11, example layers of an 8×8 Butler matrix with two cross-overs and ten vias are shown. A matrix device 1100 includes a first layer 1102, a second layer 1104, and a metal ground layer (not shown in FIG. 11) disposed between the first and second layers 1102, 1104. Eight input connectors (P1-P8) and eight output connectors (O1-O8) are operably coupled to components in the first layer 1102 or the second layer 1104 as depicted in FIG. 11. The matrix device 1100 includes 10 vias to connect the components on the first and second layers 1102, 1104, and 2 cross-overs (i.e., one cross-over on each layer 1102, 1104). In an example, the input connectors P1-P8 may be arranged such that half the input connectors are coupled to the components in the first layer 1102 and the other half are coupled to the components in the second layer 1104. Similarly, the output connectors O1-O8 may be arranged such that half the output connectors are coupled to the components in the first layer 1102 and the other half are coupled to the components in the second layer 1104. In an example, the first layer 1102, the second layer 1104, and a metal layer (not shown in FIG. 11) may be included in a single PCB and the connectors P1-P8, O1-O8 may be disposed on different edges of the single PCB such as depicted in FIG. 11. Other configuration of input and output connections may also be used.

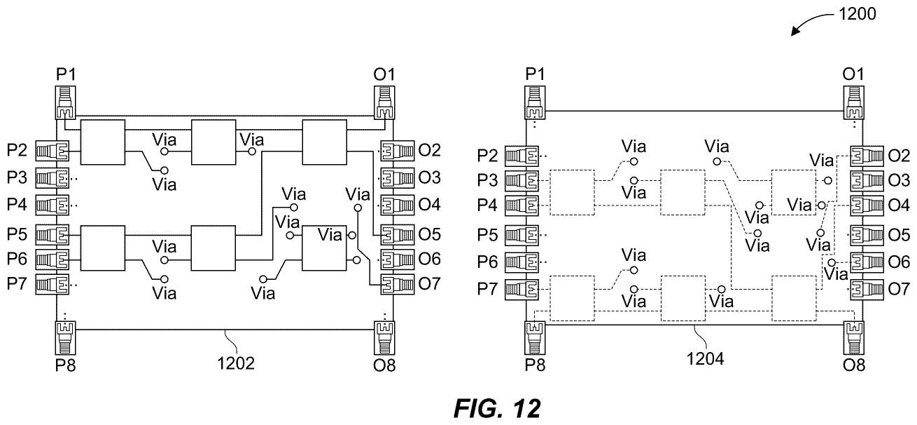

Referring to FIG. 12, example layers of an 8×8 Butler matrix with zero cross-overs and 12 vias are shown. A matrix device 1200 includes a first layer 1202, a second layer 1204, and a metal ground layer (not shown in FIG. 12) disposed between the first and second layers 1202, 1204. Eight input connectors (P1-P8) and eight output connectors (O1-O8) are operably coupled to components in the first layer 1202 or the second layer 1204 as depicted in FIG. 12. The matrix device 1200 includes 12 vias to connect the components on the first and second layers 1202, 1204. The use of 12 vias, with an insertion loss of approximately 0.2 dB-0.5 dB may replace, for example, the 16 cross-overs depicted in FIG. 6 each of which may cause an insertion loss of approximately 0.5 dB (at the center frequency).

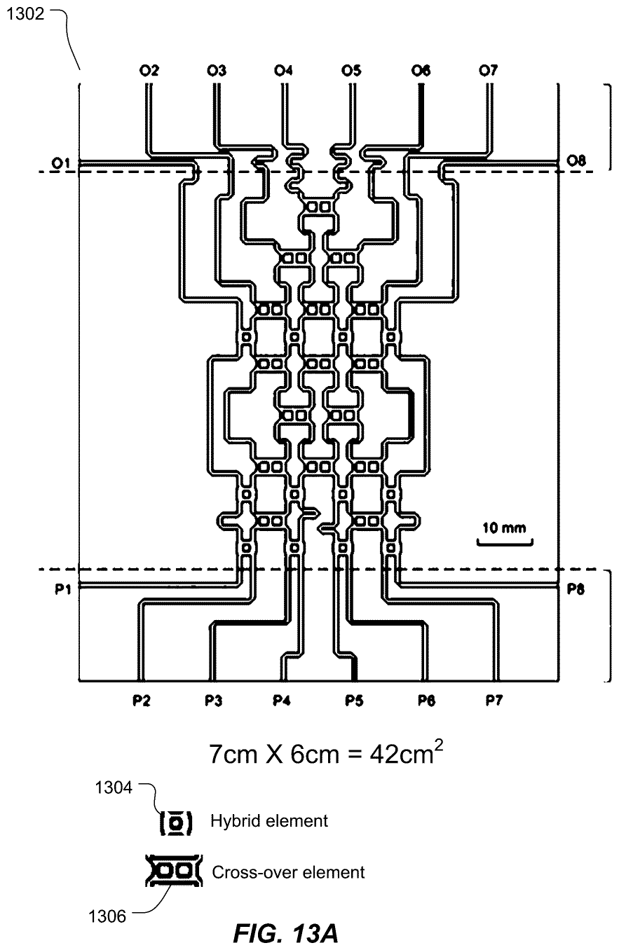

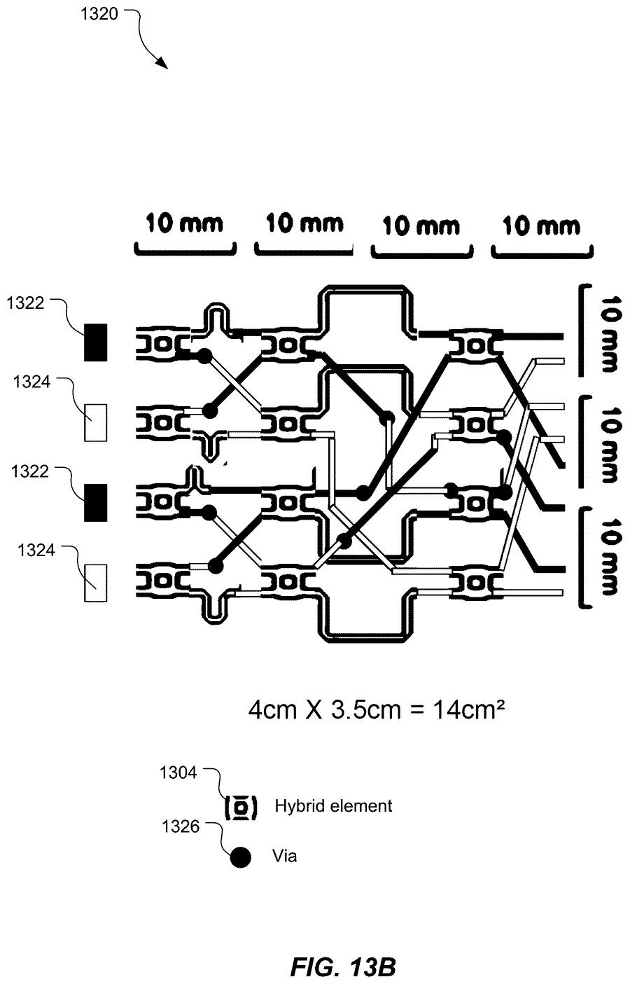

Referring to FIGS. 13A and 13B, example 8×8 Butler matrices in standard and reduced form factor configurations are shown. The example matrices are configured for a center frequency of approximately 28 GHz. A first matrix 1302 comprises microstrip elements on a PCB substrate including 12 hybrid elements 1304 and 16 cross-over elements 1306, such as described in FIG. 7. Due in part to the space required for the 16 cross-over elements 1306, the dimensions of the matrix 1302 are approximately 7 cm by 6 cm. In contrast, a second matrix 1320 in FIG. 13B utilizes the three layer approached described in FIGS. 8-10, including six hybrid elements 1304 on a first layer 1322 and six hybrid elements 1304 on a second layer 1324. There are 12 vias 1326 configured to couple the first layer 1322 and the second layer 1324. A metal ground layer (not shown in FIG. 13B) is disposed between the first and second layers 1322, 1324. The second matrix 1320 eliminates the need for the 16 cross-over elements 1306 and thus enables a reduced form factor. As an example, and not a limitation, the second matrix may be approximately 4 cm×3.5 cm. Further reduction of the form factor may be achieved by reducing the space between hybrid and phase shifter elements in the layers. In an example, the form factor of a 28 GHz 8×8 Butler matrix may be reduced to approximately 2.5 cm×2 cm. Other frequencies, matrix sizes and form factors may also be used.

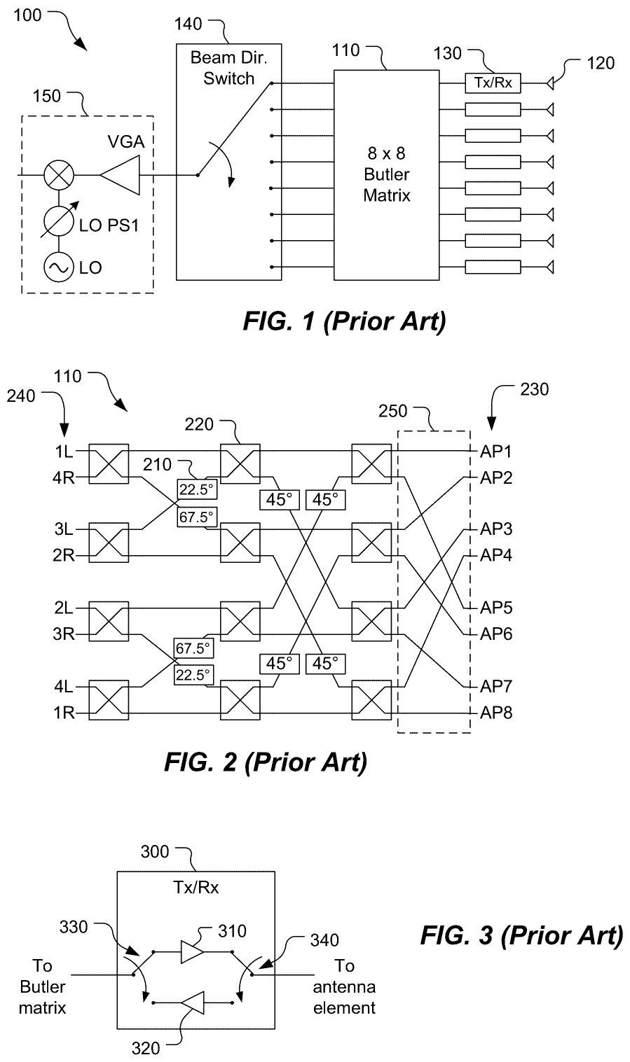

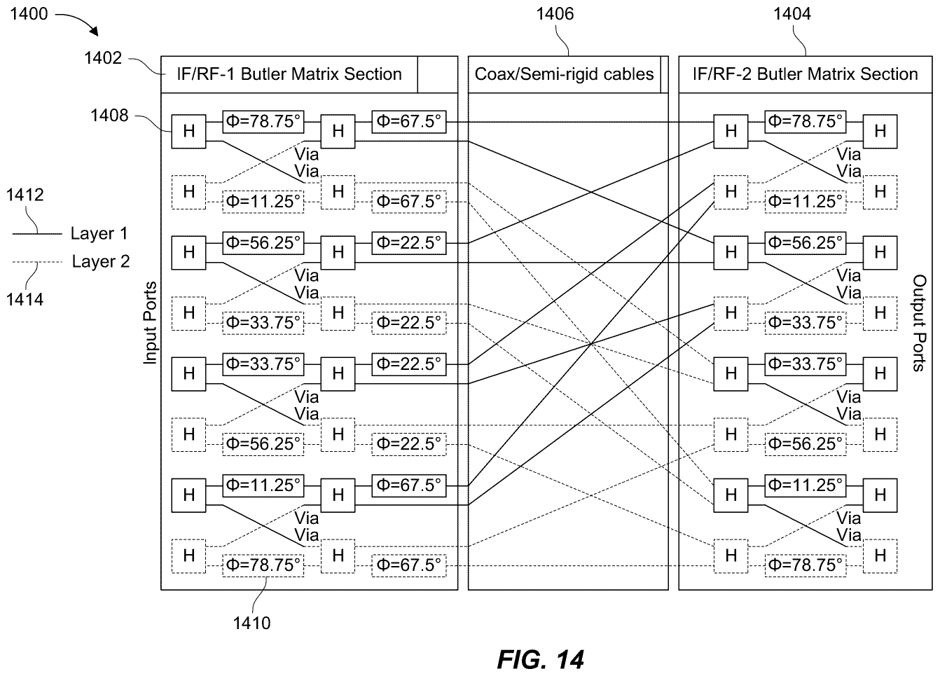

Referring to FIG. 14, a schematic diagram of an example 16×16 split Butler matrix without cross-over elements is shown. The three layer construction techniques described in FIGS. 8-10, including the first layer 902, the second layer 904, and the metal ground layer 906 disposed between the first and second layers 902, 904, may be extended to larger matrix configurations, such as 16×16 as depicted in FIG. 14, and higher order beamforming networks. In general, the hybrid elements and phase shifter elements are split into two groups, with one group disposed on a first layer, and another group disposed on a second layer. As with the 8×8 Butler matrix designs, various combinations of cross-over elements and via structures may be used to reduce the insertion loss and form factor of higher order Butler matrices. For example, a 16×16 Butler matrix may be configured with 10 vias and 9 cross-over elements. Other configuration of beamforming networks may also be realized. For example, a 16×16 split Butler matrix 1400 may be realized by breaking the matrix into a first section 1402 and a second section 1404 which are coupled to one another with coaxial or other types of semi-rigid cables in a cable section 1406. Such connectors are just examples and other means for connecting sections of a Butler matrix together may be used. Each of the sections 1402, 1404 may include combinations of hybrid elements 1408 and phase shifter elements 1410 on a first layer 1412 and a second layer 1414 as described herein. In an example, each of the sections 1402, 1404 may utilize 8 via structures to eliminate the cross-over structures in the sections. The impact of the cross-overs in the cable section 1406 may be reduced with the use of shielded cabling (e.g., coax) to form the connections as depicted in FIG. 14. The lengths of the individual cables in the cable section 1406 are typically 2-8 inches, but may vary based on the frequency and other operational requirements (e.g., form factor). The bifurcation of the matrix 1400 into two sections 1402, 1404 and the use of the cable section 1406 may eliminate the need for 44 single layer cross-over elements. The sections 1402, 1404 may also enable the addition of amplifiers to compensate for insertion loss, and/or utilize an intermediate frequency (IF) (e.g., 4-7 GHz for 28 GHz RF) in one or both of the sections 1402, 1404. The output of the second section 1404 may be provided to an antenna array (not shown in FIG. 14) such as the antenna elements 120 described in FIG. 1.

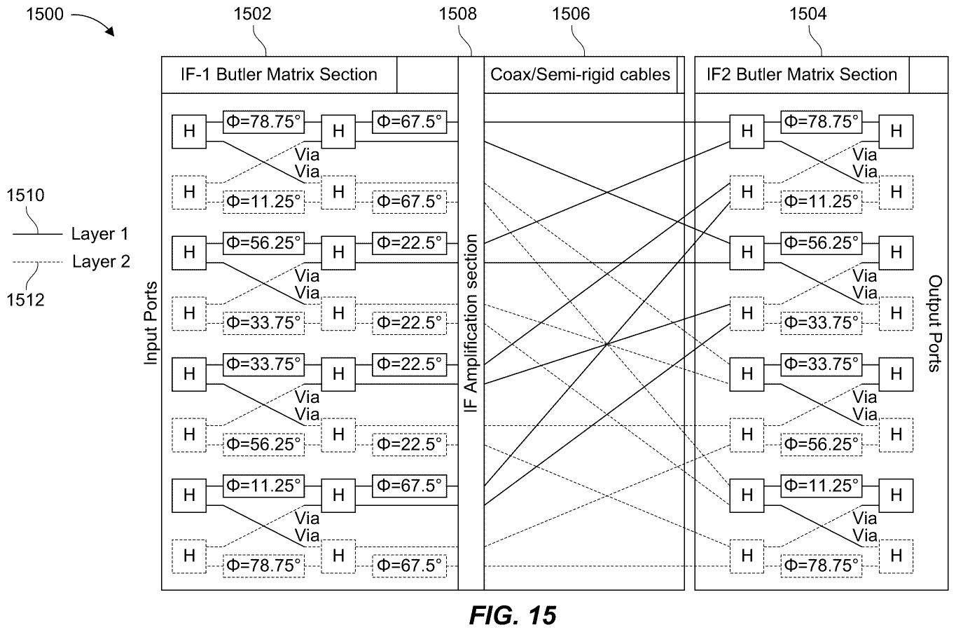

Referring to FIG. 15, a schematic diagram of a 16×16 split Butler matrix 1500 with an optional amplifier is shown. The matrix 1500 may be implemented using the IF or final RF frequencies based on operational considerations, such as bandwidth requirements. In an example, the 16×16 split Butler matrix 1500 utilizes the IF frequency (e.g., 4-7 GHz, for a 28 GHz RF output) and includes a first section 1502 and a second section 1504. Each of the first and second sections 1502, 1504 may be constructed with the three-layer technique as described in FIGS. 8-10, including respective first layers 902, second layers 904, and metal ground layers 906 disposed between the first and second layers 902, 904. The outputs of the first section 1502 may be amplified with an amplification section 1508 configured to compensate for the insertion loss and improve the overall system performance. The amplification section 1508 is depicted at the output of the first section 1502 in FIG. 15, but it may be disposed at other locations between the first and second section 1502, 1504. The sections 1502, 1504, and the amplification section 1508 may be coupled to one another with coaxial or other types of semi-rigid cables in a cable section 1506. Each of the sections 1502, 1504 may include combinations of hybrid elements and phase shifter elements on a first layer 1510 and a second layer 1512 as described in FIGS. 8-10. In an example, each of the sections 1502, 1504 may utilize 8 via structures to eliminate the cross-over structures in the sections. In example, the output of the second section 1504 may be provided to a phased antenna array (not shown in FIG. 15), and the amplification section 1508 may be configured to compensate for any amplitude imbalances in the outputs to the antenna array. In operation, the amplification section 1508 may cause phase imbalances and the configurations of the phase shifter elements may be modified based on the imbalances.

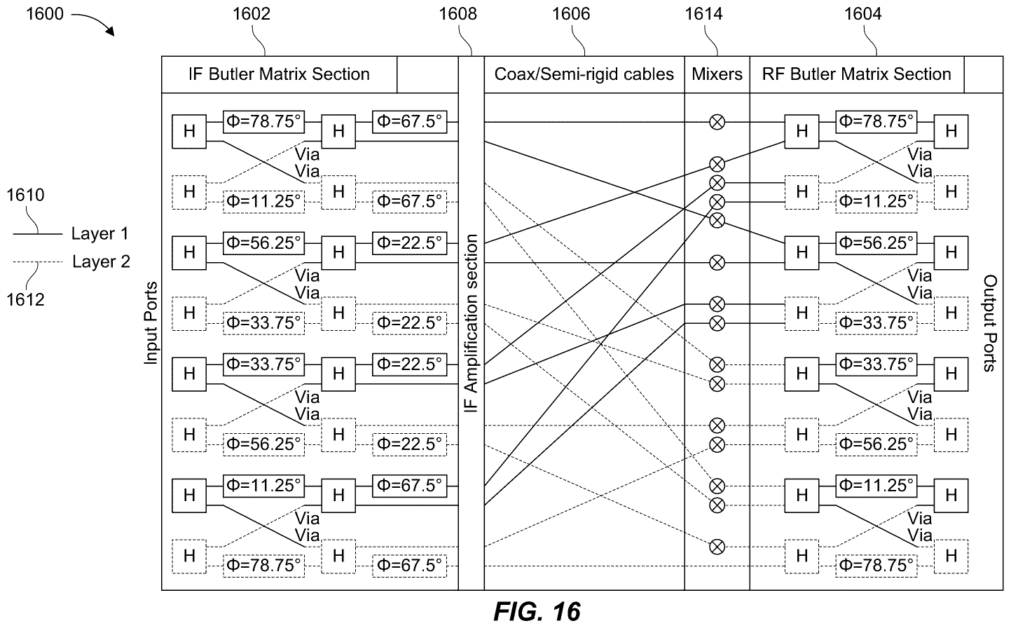

Referring to FIG. 16, a schematic diagram of a 16×16 split IF-RF Butler matrix 1600 without cross-over elements is shown. The matrix 1600 receives an IF frequency input (e.g., 4-7 GHz, for a 28 GHz RF output) to a first section 1602. Utilizing the IF may reduce the insertion loss as compared to utilizing the RF in the first stage. The output of the first section may be amplified with an amplification section 1608, and cable section 1606 may be configured to feed to a mixer section 1614. Amplifiers for the IF may be more efficient and consume less power as compared to amplifiers configured to operate at the RF. The IF amplifiers may also be configured to adjust potential amplitude mismatches in the overall chain. The mixer section 1614 is configured to upconvert the IF signal to the final RF signal (e.g., 28 GHz). A second section 1604 is configured to receive the RF signal. Each of the first and second sections 1602, 1604 may be constructed with the three-layer technique as described in FIGS. 8-10, including respective first layers, second layers, and metal ground layers 906 disposed between the respective first and second layers. Each of the sections 1602, 1604 may include combinations hybrid elements and phase shifter elements on a first layer 1610 and a second layer 1612 as described in FIGS. 8-10. In an example, each of the sections 1602, 1604 may utilize 8 via structures to eliminate the cross-over structures in the sections. In operation, the amplification and/or mixer sections 1608, 1614 may cause phase imbalances and the configurations of the phase shifter elements may be modified based on the imbalances. For example, phase mismatches may be addressed via Lo phase shifters and/or adding phase shifters at the IF band. Digital adjustments may also be implemented to compensate for phase mismatches.

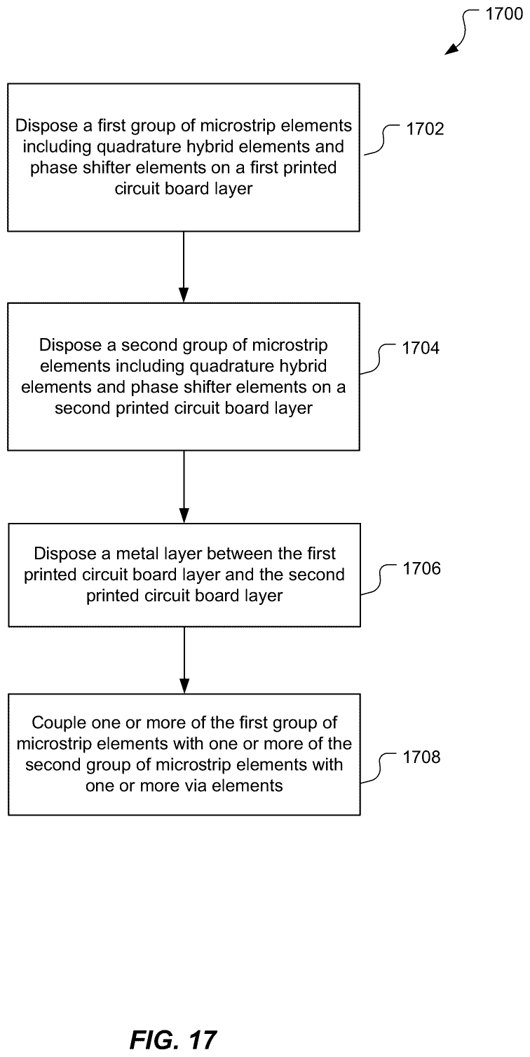

Referring to FIG. 17, with further reference to FIGS. 1-16, a method 1700 for fabricating a low-loss small form-factor beamforming network includes the stages shown. The method 1700 is, however, an example and not limiting. The method 1700 may be altered, e.g., by having stages added, removed, rearranged, combined, performed concurrently, and/or having single stages split into multiple stages. Circuit manufacturing techniques as known in the art may be used to implement the method 1700. For example, disposing microstrip elements on a PCB layer may include coating a dielectric with a metal, coating the metal with photoresist, exposing the photoresist with an image based on the microstrip elements, and etching away the excess metal. Other circuit fabrication techniques may also be used.

At stage 1702, the method includes disposing a first group of microstrip elements including quadrature hybrid elements and phase shifter elements on a first printed circuit board layer. In an example, the beamforming network may be a Butler matrix may be an 8×8 matrix such as described in FIGS. 8-10. The first group of microstrip elements may include six quadrature hybrids and four phase shifters such as depicted in the first layer 902 in FIG. 10. The microstrip elements may be disposed on a PCB material and coupled to connectors located at the edges of the PCB, such as depicted in FIGS. 11 and 12.

At stage 1704, the method includes disposing a second group of microstrip elements including quadrature hybrid elements and phase shifter elements on a second printed circuit board layer. Continuing the example 8×8 Butler matrix, the second group of microstrip elements may include six quadrature hybrids and four phase shifters such as depicted in the second layer 904 in FIG. 10. The second group of microstrip elements may be disposed on a PCB material and coupled to connectors located at the edges of the PCB, such as depicted in FIGS. 11 and 12.

At stage 1706, the method includes disposing a metal layer between the first printed circuit board layer and the second printed circuit board layer. The metal layer may include copper cladding, or other conductors (e.g., Ag, Au, etc.) and may be coupled to a ground in an antenna system. For example, the metal ground layer 906 may be clad to one side of either or both of the first and second printed circuit boards and configured to reduce the RF interference (and associated current loops) between the layers.

At stage 1708, the method includes coupling one or more of the first group of microstrip elements with one or more of the second group of microstrip elements with one or more vias. The vias are configured to be electrically isolated from the metal layer (i.e., not in electrical contact) and enable current flow between the first and second printed circuit board layers. For example, the 8×8 matrix described in FIG. 10 includes four vias (e.g., vias 1006a-d) configured to couple one or more microstrip elements in the first layer with one or more microstrip elements in the second layer. Other configurations may include additional vias, such as 10 vias as depicted in FIGS. 11 and 12 vias depicted in FIG. 12.

While the method 1700 utilizes two printed circuit board layers, the disclosure is not so limited. Additional layers (e.g., 3, 4, 5, etc.) and intervening metal layers may be used for higher order matrices. The 8×8 and 16×16 Butler matrices described herein are examples, and not limitations as the method 1700 may be utilized for higher order beam forming circuits. Further, the microstrip components disposed on dielectric substrates (e.g., PCB materials) in the example matrices described herein may be implemented as striplines within a dielectric substrate. Other manufacturing techniques may also be used to fabricate low-loss small form-factor beamforming networks and described herein.

Other examples and implementations are within the scope of the disclosure and appended claims. For example, configurations other than those shown may be used. Also, due to the nature of software and computers, functions described above can be implemented using software executed by a processor, hardware, firmware, hardwiring, or a combination of any of these. Features implementing functions may also be physically located at various positions, including being distributed such that portions of functions are implemented at different physical locations.

As used herein, the singular forms “a,” “an,” and “the” include the plural forms as well, unless the context clearly indicates otherwise. The terms “comprises,” “comprising,” “includes,” and/or “including,” as used herein, specify the presence of stated features, integers, steps, operations, elements, and/or components, but do not preclude the presence or addition of one or more other features, integers, steps, operations, elements, components, and/or groups thereof.

Also, as used herein, “or” as used in a list of items (possibly prefaced by “at least one of” or prefaced by “one or more of”) indicates a disjunctive list such that, for example, a list of “at least one of A, B, or C,” or a list of “one or more of A, B, or C” or a list of “A or B or C” means A, or B, or C, or AB (A and B), or AC (A and C), or BC (B and C), or ABC (i.e., A and B and C), or combinations with more than one feature (e.g., AA, AAB, ABBC, etc.). Thus, a recitation that an item, e.g., a processor, is configured to perform a function regarding at least one of A or B, or a recitation that an item is configured to perform a function A or a function B, means that the item may be configured to perform the function regarding A, or may be configured to perform the function regarding B, or may be configured to perform the function regarding A and B. For example, a phrase of “a processor configured to measure at least one of A or B” or “a processor configured to measure A or measure B” means that the processor may be configured to measure A (and may or may not be configured to measure B), or may be configured to measure B (and may or may not be configured to measure A), or may be configured to measure A and measure B (and may be configured to select which, or both, of A and B to measure). Similarly, a recitation of a means for measuring at least one of A or B includes means for measuring A (which may or may not be able to measure B), or means for measuring B (and may or may not be configured to measure A), or means for measuring A and B (which may be able to select which, or both, of A and B to measure). As another example, a recitation that an item, e.g., a processor, is configured to at least one of perform function X or perform function Y means that the item may be configured to perform the function X, or may be configured to perform the function Y, or may be configured to perform the function X and to perform the function Y. For example, a phrase of “a processor configured to at least one of measure X or measure Y” means that the processor may be configured to measure X (and may or may not be configured to measure Y), or may be configured to measure Y (and may or may not be configured to measure X), or may be configured to measure X and to measure Y (and may be configured to select which, or both, of X and Y to measure).

As used herein, unless otherwise stated, a statement that a function or operation is “based on” an item or condition means that the function or operation is based on the stated item or condition and may be based on one or more items and/or conditions in addition to the stated item or condition.

The systems and devices discussed above are examples. Various configurations may omit, substitute, or add various procedures or components as appropriate. For instance, features described with respect to certain configurations may be combined in various other configurations. Different aspects and elements of the configurations may be combined in a similar manner. Also, technology evolves and, thus, many of the elements are examples and do not limit the scope of the disclosure or claims.

A wireless communication system is one in which communications are conveyed wirelessly, i.e., by electromagnetic and/or acoustic waves propagating through atmospheric space rather than through a wire or other physical connection. A wireless communication network may not have all communications transmitted wirelessly, but is configured to have at least some communications transmitted wirelessly. Further, the term “wireless communication device,” or similar term, does not require that the functionality of the device is exclusively, or evenly primarily, for communication, or that communication using the wireless communication device is exclusively, or evenly primarily, wireless, or that the device be a mobile device, but indicates that the device includes wireless communication capability (one-way or two-way), e.g., includes at least one radio (each radio being part of a transmitter, receiver, or transceiver) for wireless communication.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations, and does not limit the scope, applicability, or configurations of the claims. Rather, the preceding description of the configurations provides a description for implementing described techniques. Various changes may be made in the function and arrangement of elements.

Having described several example configurations, various modifications, alternative constructions, and equivalents may be used. For example, the above elements may be components of a larger system, wherein other rules may take precedence over or otherwise modify the application of the disclosure. Also, a number of operations may be undertaken before, during, or after the above elements are considered. Accordingly, the above description does not bound the scope of the claims.

Unless otherwise indicated, “about” and/or “approximately” as used herein when referring to a measurable value such as an amount, a temporal duration, and the like, encompasses variations of ±20% or ±10%, ±5%, or +0.1% from the specified value, as appropriate in the context of the systems, devices, circuits, methods, and other implementations described herein. Unless otherwise indicated, “substantially” as used herein when referring to a measurable value such as an amount, a temporal duration, a physical attribute (such as frequency), and the like, also encompasses variations of ±20% or ±10%, ±5%, or +0.1% from the specified value, as appropriate in the context of the systems, devices, circuits, methods, and other implementations described herein.

A statement that a value exceeds (or is more than or above) a first threshold value is equivalent to a statement that the value meets or exceeds a second threshold value that is slightly greater than the first threshold value, e.g., the second threshold value being one value higher than the first threshold value in the resolution of a computing system. A statement that a value is less than (or is within or below) a first threshold value is equivalent to a statement that the value is less than or equal to a second threshold value that is slightly lower than the first threshold value, e.g., the second threshold value being one value lower than the first threshold value in the resolution of a computing system.

Implementation examples are described in the following numbered clauses:
Clause 1. A beamforming network configured to feed a phased array of antenna elements, comprising: a first group of microstrip elements on a first layer of a printed circuit board, a second group of microstrip elements on a second layer of the printed circuit board, a metal layer disposed between the first layer and the second layer, and a plurality of vias configured to couple one or more elements in the first group of microstrip elements with one or more elements in the second group of microstrip elements.
Clause 2. The beamforming network of clause 1 wherein the first group of microstrip elements includes one or more quadrature hybrid elements and one or more phase shifter elements, and the second group of microstrip elements includes one or more quadrature hybrid elements and one or more phase shifter elements.
Clause 3. An antenna beamforming system, comprising: a first printed circuit board layer comprising a first group of microstrip elements including quadrature hybrid elements and phase shifter elements; a second printed circuit board layer comprising a second group of microstrip elements including quadrature hybrid elements and phase shifter elements; a metal ground layer disposed between the first printed circuit board layer and the second printed circuit board layer; and a plurality of vias configured to couple one or more of the first group of microstrip elements with one or more of the second group of microstrip elements.
Clause 4. The antenna beamforming system of clause 3 wherein the first printed circuit board layer, the second printed circuit board layer, and the metal ground layer comprise a single printed circuit board.
Clause 5. The antenna beamforming system of clause 4 further comprising a plurality of input ports disposed on a first edge of the single printed circuit board and a plurality of output ports disposed on a second edge of the single printed circuit board.
Clause 6. The antenna beamforming system of clause 3 wherein the first group of microstrip elements includes one or more cross-over elements, and the second group of microstrip elements includes one or more cross-over elements.
Clause 7. The antenna beamforming system of clause 3 comprising an 8×8 Butler matrix, wherein the plurality of vias includes 4 vias, the first group of microstrip elements includes two cross-over elements, and the second group of microstrip elements includes two cross-over elements.
Clause 8. The antenna beamforming system of clause 3 comprising an 8×8 Butler matrix, wherein the plurality of vias includes 10 vias, the first group of microstrip elements includes one cross-over element, and the second group of microstrip elements includes one cross-over element.
Clause 9. The antenna beamforming system of clause 3 comprising an 8×8 Butler matrix, wherein the plurality of vias includes 12 vias.
Clause 10. The antenna beamforming system of clause 3 wherein the first printed circuit board layer further comprises a first plurality of input ports and a first plurality of output ports, and the second printed circuit board layer further comprises a second plurality of input ports and a second plurality of output ports.
Clause 11. An antenna beamforming system, comprising: a first section comprising: a first printed circuit board layer comprising a first group of microstrip elements including quadrature hybrid elements and phase shifter elements; a second printed circuit board layer comprising a second group of microstrip elements including quadrature hybrid elements and phase shifter elements; a first metal ground layer disposed between the first printed circuit board layer and the second printed circuit board layer; a first plurality of vias configured to couple one or more of the first group of microstrip elements with one or more of the second group of microstrip elements; a plurality of input ports configured to receive a radio frequency input; a second section comprising: a third printed circuit board layer comprising a third group of microstrip elements including quadrature hybrid elements and phase shifter elements; a fourth printed circuit board layer comprising a fourth group of microstrip elements including quadrature hybrid elements and phase shifter elements; a second metal ground layer disposed between the third printed circuit board layer and the fourth printed circuit board layer; a second plurality of vias configured to couple one or more of the third group of microstrip elements with one or more of the fourth group of microstrip elements; a plurality of output ports configured to output a radio frequency output to an antenna array; and a cable section configured to operably couple the first section and the second section.
Clause 12. The antenna beamforming system of clause 11 wherein the cable section comprises a plurality of coaxial cables.
Clause 13. The antenna beamforming system of clause 11 wherein the first printed circuit board layer, the second printed circuit board layer, and the first metal ground layer comprise a first section printed circuit board, and the third printed circuit board layer, the fourth printed circuit board layer, and the second metal ground layer comprise a second section printed circuit board.
Clause 14. The antenna beamforming system of clause 13 wherein the first section printed circuit board further comprises a plurality of output ports, the second section printed circuit board further comprises a plurality of input ports, and the cable section is configured to couple each output port in the plurality of output ports on the first section printed circuit board with the an associated input port in the plurality of input ports on the second section printed circuit board.
Clause 15. The antenna beamforming system of clause 11 further comprising an amplification section disposed between the first section and the second section and configured to amplify signals output from the first section.
Clause 16. The antenna beamforming system of clause 15 wherein the amplification section is configured to compensate for an amplitude imbalance in the radio frequency output to the antenna array.
Clause 17. The antenna beamforming system of clause 11 further comprising a mixer section disposed between the first section and the second section and configured to upconvert signals output from the first section.
Clause 18. The antenna beamforming system of clause 11 wherein the radio frequency input to the first section is at an intermediate frequency and the output of the second section is an operational radio frequency.
Clause 19. The antenna beamforming system of clause 11 wherein the radio frequency input to the first section is at an intermediate frequency and the output of the second section is at the intermediate frequency.
Clause 20. The antenna beamforming system of clause 11 wherein the plurality of input ports in the first section is 16 input ports, the plurality of output ports on the second section is 16 output ports, the first plurality of vias is 8 vias, and the second plurality of vias is 8 vias.
Clause 21. The antenna beamforming system of clause 11 wherein the first group of microstrip elements, the second group of microstrip elements, the third group of microstrip elements, and the fourth group of microstrip elements each include at least one cross-over element.
Clause 22. The antenna beamforming system of clause 11 wherein a distance between the first section and the second section is in a range of 2 inches to 8 inches.
Clause 23. A method of fabricating a low-loss small form-factor beamforming network, comprising: disposing a first group of microstrip elements including quadrature hybrid elements and phase shifter elements on a first printed circuit board layer; disposing a second group of microstrip elements including quadrature hybrid elements and phase shifter elements on a second printed circuit board layer; disposing a metal layer between the first printed circuit board layer and the second printed circuit board layer; and coupling one or more of the first group of microstrip elements with one or more of the second group of microstrip elements with one or more vias.
Clause 24. The method of clause 23 wherein the first printed circuit board layer, the second printed circuit board layer, and the metal layer comprise a single printed circuit board.
Clause 25. The method of clause 24 further comprising: coupling a first plurality of input connectors to the first group of microstrip elements, wherein the first plurality of input connectors are disposed on a first edge of the single printed circuit board; coupling a second plurality of input connectors to the second group of microstrip elements, wherein the second plurality of input connectors are disposed on the first edge of the single printed circuit board; coupling a first plurality of output connectors to the first group of microstrip elements, wherein the first plurality of output connectors are disposed on a second edge of the single printed circuit board; and coupling a second plurality of output connectors to the second group of microstrip elements, wherein the second plurality of output connectors are disposed on the second edge of the single printed circuit board.
Clause 26. The method of clause 23 further comprising: coupling a first plurality of input connectors and output connectors to the first group of microstrip elements on the first printed circuit board layer; and coupling a second plurality of input connectors and output connectors to the second group of microstrip elements on the second printed circuit board layer.
Clause 27. The method of clause 23 further comprising disposing one or more cross-over elements on the first printed circuit board layer, and disposing one or more cross-over elements on the second printed circuit board layer.
Clause 28. The method of clause 23 wherein the first printed circuit board layer and the second printed circuit board layer comprise a first Butler matrix section, and the method further comprises: fabricating a second Butler matrix section including: disposing a third group of microstrip elements including quadrature hybrid elements and phase shifter elements on a third printed circuit board layer; disposing a fourth group of microstrip elements including quadrature hybrid elements and phase shifter elements on a fourth printed circuit board layer; disposing a metal layer between the third printed circuit board layer and the fourth printed circuit board layer; coupling one or more of the third group of microstrip elements with one or more of the fourth group of microstrip elements with one or more vias; and coupling the first Butler matrix section to the second Butler matrix section with a plurality of cables.
Clause 29. The method of clause 28 wherein the plurality of cables includes coaxial cables.

1. A beamforming network configured to feed a phased array of antenna elements, comprising: a first group of microstrip elements on a first layer of a printed circuit board, a second group of microstrip elements on a second layer of the printed circuit board, a metal layer disposed between the first layer and the second layer, and a plurality of vias configured to couple one or more elements in the first group of microstrip elements with one or more elements in the second group of microstrip elements.

2. The beamforming network of claim 1 wherein the first group of microstrip elements includes one or more quadrature hybrid elements and one or more phase shifter elements, and the second group of microstrip elements includes one or more quadrature hybrid elements and one or more phase shifter elements.

3. An antenna beamforming system, comprising:
a first printed circuit board layer comprising a first group of microstrip elements including quadrature hybrid elements and phase shifter elements;
a second printed circuit board layer comprising a second group of microstrip elements including quadrature hybrid elements and phase shifter elements;
a metal ground layer disposed between the first printed circuit board layer and the second printed circuit board layer; and
a plurality of vias configured to couple one or more of the first group of microstrip elements with one or more of the second group of microstrip elements.

4. The antenna beamforming system of claim 3 wherein the first printed circuit board layer, the second printed circuit board layer, and the metal ground layer comprise a single printed circuit board.

5. The antenna beamforming system of claim 4 further comprising a plurality of input ports disposed on a first edge of the single printed circuit board and a plurality of output ports disposed on a second edge of the single printed circuit board.

6. The antenna beamforming system of claim 3 wherein the first group of microstrip elements includes one or more cross-over elements, and the second group of microstrip elements includes one or more cross-over elements.

7. The antenna beamforming system of claim 3 comprising an 8×8 Butler matrix, wherein the plurality of vias includes 4 vias, the first group of microstrip elements includes two cross-over elements, and the second group of microstrip elements includes two cross-over elements.

8. The antenna beamforming system of claim 3 comprising an 8×8 Butler matrix, wherein the plurality of vias includes 10 vias, the first group of microstrip elements includes one cross-over element, and the second group of microstrip elements includes one cross-over element.

9. The antenna beamforming system of claim 3 comprising an 8×8 Butler matrix, wherein the plurality of vias includes 12 vias.

10. The antenna beamforming system of claim 3 wherein the first printed circuit board layer further comprises a first plurality of input ports and a first plurality of output ports, and the second printed circuit board layer further comprises a second plurality of input ports and a second plurality of output ports.

11. An antenna beamforming system, comprising:
a first section comprising:
a first printed circuit board layer comprising a first group of microstrip elements including quadrature hybrid elements and phase shifter elements;
a second printed circuit board layer comprising a second group of microstrip elements including quadrature hybrid elements and phase shifter elements;
a first metal ground layer disposed between the first printed circuit board layer and the second printed circuit board layer;
a first plurality of vias configured to couple one or more of the first group of microstrip elements with one or more of the second group of microstrip elements;
a plurality of input ports configured to receive a radio frequency input;
a second section comprising:
a third printed circuit board layer comprising a third group of microstrip elements including quadrature hybrid elements and phase shifter elements;
a fourth printed circuit board layer comprising a fourth group of microstrip elements including quadrature hybrid elements and phase shifter elements;
a second metal ground layer disposed between the third printed circuit board layer and the fourth printed circuit board layer;
a second plurality of vias configured to couple one or more of the third group of microstrip elements with one or more of the fourth group of microstrip elements;
a plurality of output ports configured to output a radio frequency output to an antenna array; and
a cable section configured to operably couple the first section and the second section.

12. The antenna beamforming system of claim 11 wherein the cable section comprises a plurality of coaxial cables.

13. The antenna beamforming system of claim 11 wherein the first printed circuit board layer, the second printed circuit board layer, and the first metal ground layer comprise a first section printed circuit board, and the third printed circuit board layer, the fourth printed circuit board layer, and the second metal ground layer comprise a second section printed circuit board.

14. The antenna beamforming system of claim 13 wherein the first section printed circuit board further comprises a plurality of output ports, the second section printed circuit board further comprises a plurality of input ports, and the cable section is configured to couple each output port in the plurality of output ports on the first section printed circuit board with the an associated input port in the plurality of input ports on the second section printed circuit board.

15. The antenna beamforming system of claim 11 further comprising an amplification section disposed between the first section and the second section and configured to amplify signals output from the first section.

16. The antenna beamforming system of claim 15 wherein the amplification section is configured to compensate for an amplitude imbalance in the radio frequency output to the antenna array.

17. The antenna beamforming system of claim 11 further comprising a mixer section disposed between the first section and the second section and configured to upconvert signals output from the first section.

18. The antenna beamforming system of claim 11 wherein the radio frequency input to the first section is at an intermediate frequency and the output of the second section is an operational radio frequency.

19. The antenna beamforming system of claim 11 wherein the radio frequency input to the first section is at an intermediate frequency and the output of the second section is at the intermediate frequency.

20. The antenna beamforming system of claim 11 wherein the plurality of input ports in the first section is 16 input ports, the plurality of output ports on the second section is 16 output ports, the first plurality of vias is 8 vias, and the second plurality of vias is 8 vias.

21. The antenna beamforming system of claim 11 wherein the first group of microstrip elements, the second group of microstrip elements, the third group of microstrip elements, and the fourth group of microstrip elements each include at least one cross-over element.

22. The antenna beamforming system of claim 11 wherein a distance between the first section and the second section is in a range of 2 inches to 8 inches.
